(19) United States
(12) Patent Application Publication
(10) Pub. No.: US 2022/0248556 A1
(43) Pub. Date: Aug. 4, 2022

(54) Small Cell Telecommunication Structure

(71) Applicant: ORIGIN Engineering LLC, Windsor, CO (US)

(72) Inventor: Matthew J. Chase, Windsor, CO (US)

(21) Appl. No.: 17/649,298

(22) Filed: Jan. 28, 2022

Related U.S. Application Data
(60) Provisional application No. 63/199,911, filed on Feb. 2, 2021.

(51) Int. Cl. H05K 7/18; H05K 5/02

(52) U.S. Cl. CPC H05K 7/186; H04W 88/08; H05K 5/0213

(57) ABSTRACT

An example small cell telecommunication structure includes a cabinet opening both on a first side and on a second side. The first side of the cabinet is disposed opposite to the second side. A structural backplane is provided within the cabinet. The structural backplane is made of a single slotted and tabbed flat sheet formed into a first sidewall, a back wall, and a second sidewall. The first sidewall is parallel to the second sidewall, and both the first and second sidewalls are perpendicular to the back wall. An electronics enclosure is provided within the cabinet, having an interior space formed by the first and second sidewalls and the back wall of the structural backplane for housing telecommunications equipment. A power panel is disposed on the second side of the cabinet for providing electrical connections for the telecommunications equipment.

### PRIORITY CLAIM

This application claims the priority benefit of U.S. Provisional Patent Application No. 63/199,911 filed Feb. 2, 2021 for “Small Cell Telecommunication Structure” of Matthew J. Chase, hereby incorporated by reference in its entirety as though fully set forth herein.

### BACKGROUND

To make 5G wireless services a reality, small cell sites are being installed to provide coverage. 5G small cell sites must be lower to the ground and in closer proximity to one another than previous generations of wireless telecommunications. In dense, urban areas, 5G small cell sites are being installed all over city streets, buildings, and neighborhoods. To avoid clutter, cell phone carriers and municipalities recognize that existing light poles and power poles provide platforms for 5G small cell sites. Hence highly integrated structures are needed to meet the requirements for providing wireless service while minimizing disruption during installation and repairs. These integrated structures will become common in the landscape and thus need to fit in seamlessly with the surroundings, while complying with local, state, and federal ordinances, while still based on a standard for manufacturing and installation.

### BRIEF DESCRIPTION OF THE DRAWINGS

FIG. 1 are isometric views showing a first side and a second side of an example small cell telecommunication structure.

FIG. 2 is a perspective view of the first side of an example small cell telecommunication structure with the first side enclosure doors closed.

FIG. 3 is a perspective view of the first side of an example small cell telecommunication structure with the first side enclosure doors open.

FIG. 4 corresponds to FIG. 3, and shows electronics and shelving removed from an interior portion of the first side of the example small cell telecommunication structure.

FIG. 5 is a close-up view of an example hinge seen in FIGS. 3 and 4.

FIG. 6 is a close-up view of an example louver seen in FIGS. 3 and 4.

FIG. 7 is a perspective view of the second side of the example small cell telecommunication structure.

FIG. 8 is a plan view corresponding to FIG. 7.

FIG. 9 is a perspective view of the second side of the example small cell telecommunication structure with the enclosure doors open.

FIG. 10 is a plan view corresponding to FIG. 9.

FIG. 11 is a perspective view of the second side of the example small cell telecommunication structure with an interior cover of an electrical panel removed.

FIG. 12 is a perspective view of the example electrical panel for the example small cell telecommunication structure.

### DETAILED DESCRIPTION

Traditional utility poles are built from square or round tubing or pipes. Cabinets for mounting telecommunications equipment are typically mounted to the outside of the pole. This can give the utility poles an unsightly appearance. In addition, access to the interior space may only be provided through a door on the front side of the cabinet as the cabinet is mounted on the back side to the pole.

A small cell telecommunication structure is disclosed which provides a more cost effective solution that eliminates access issues, eliminates water penetrating issues, and is aesthetically pleasing.

In an example, the telecommunication structure is implemented as a cabinet for installation around the outside circumference of traditional telecom poles. The cabinet may house small cell telecommunication devices and associated electrical power. Of course, the structure is not limited only to use with telecom poles or to house small cell telecommunication devices. Other applications of the structure will also be apparent to those having ordinary skill in the art after becoming familiar with the teachings herein, and the scope of this disclosure is not intended to be limited to any particular end-use.

In an example, the cabinet includes a flat sheet that is slotted and tabbed to configure the shape into a structural member. The flat plates or sheets enable flat-surface equipment mounting locations within the interior of the cabinet (e.g., for installing small cell telecommunication devices). For example, the rectangular/flat interior space enables the efficient installation of rectangular/flat equipment in the interior space. In addition, the small cell telecommunication structure is configurable for a variety of different types, sizes, and configurations of equipment.

Equipment mounting locations are provided on the first and second sidewalls and on the back wall of the structural backplane. The equipment mounting locations enable mounting the telecommunications equipment. For example, slotted connectors may be provided. Slotted connectors enable installation of backplanes of the telecommunications equipment and/or other hardware in the cabinet without the need for installation tools and hardware (e.g., screwdrivers and screws).

Before continuing, it is noted that as used herein, the terms “includes” and “including” mean, but is not limited to, “includes” or “including” and “includes at least” or “including at least.” The term “based on” means “based on” and “based at least in part on.”

It is also noted that the examples described herein are provided for purposes of illustration, and are not intended to be limiting. By way of illustration, the small cell telecommunication structure is not limited to use with any particular equipment or to any particular installation location. Other devices and/or device configurations may be utilized to carry out the operations described herein.

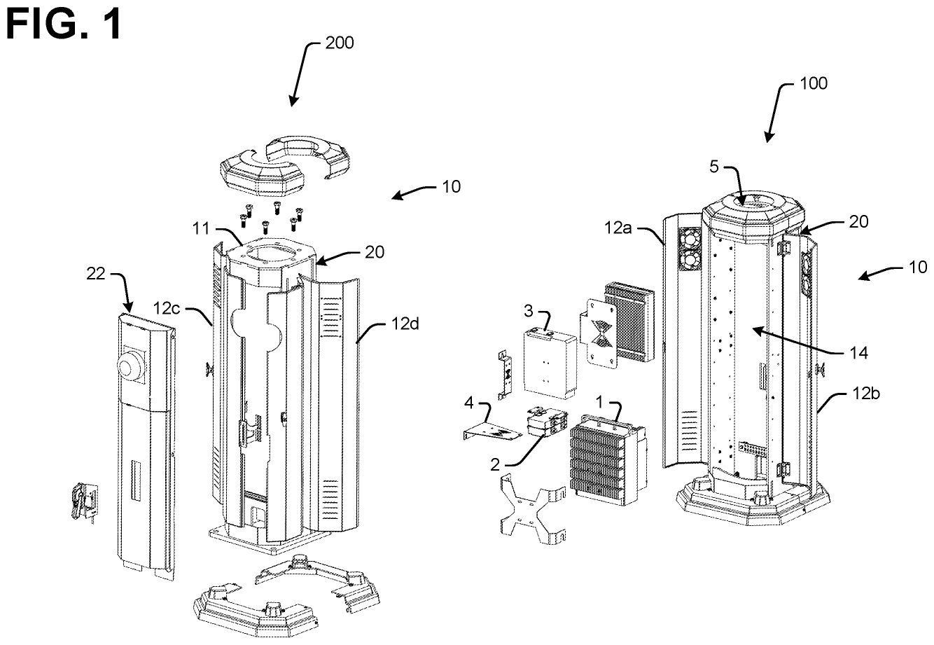

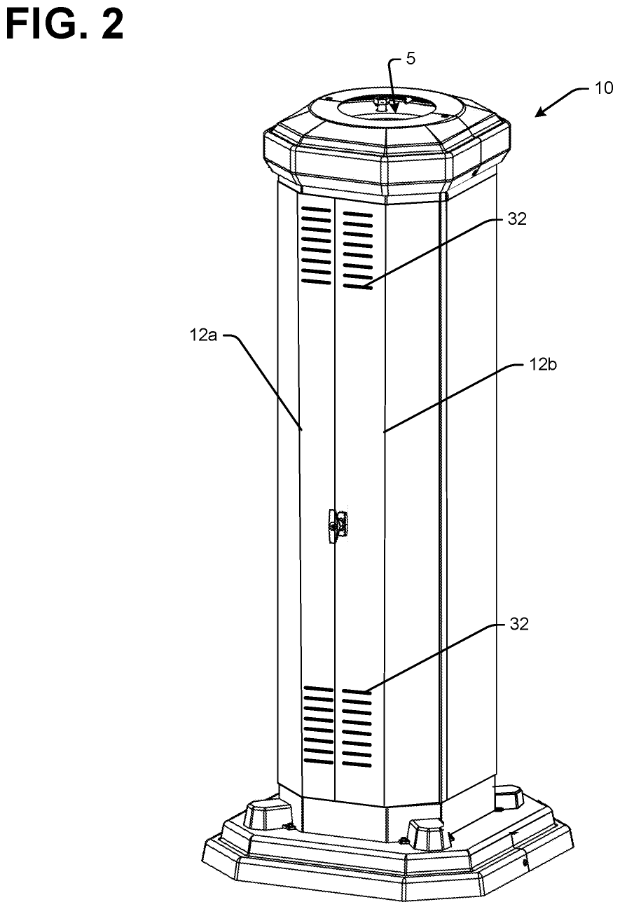

FIG. 1 are isometric views showing a first side (right view 100 in FIG. 1) and a second side (left view 200 in FIG. 1) of an example small cell telecommunication structure 10. FIG. 2 is a perspective view of the first side of an example small cell telecommunication structure 10 with the first side enclosure doors 12a and 12b closed.

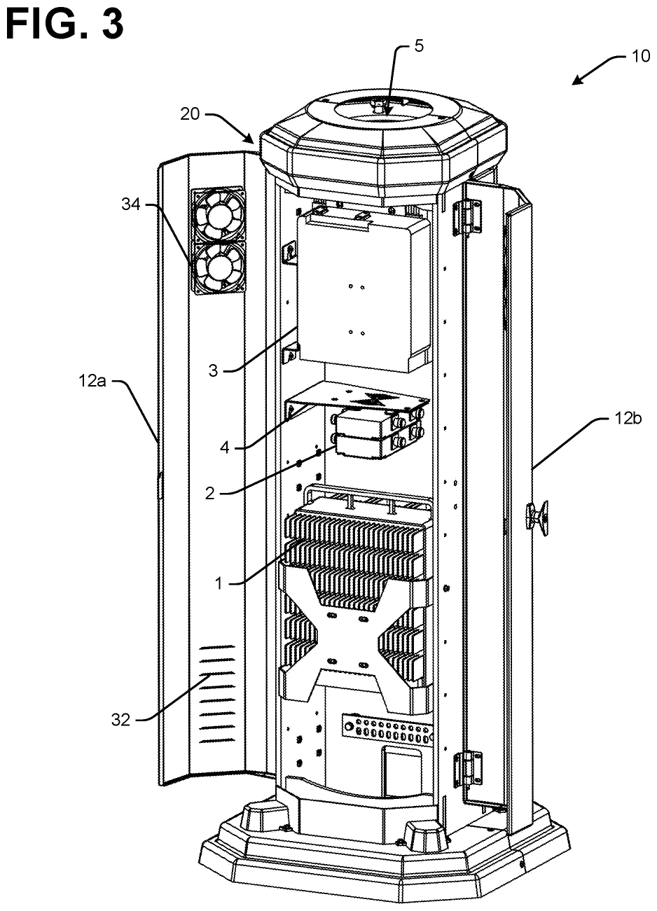

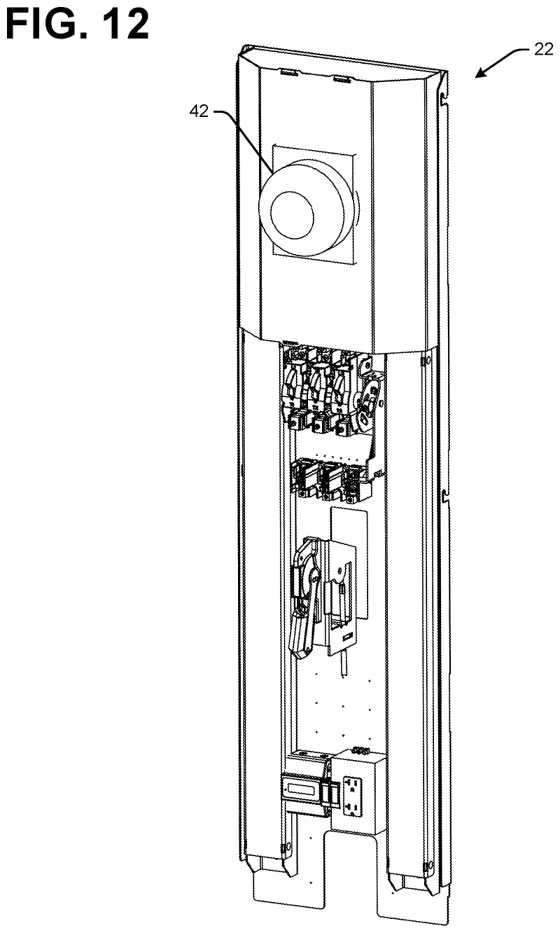

An example small cell telecommunication structure 10 includes a cabinet 20. An electronics enclosure 14 (the interior portion) is provided within one side of the cabinet 20. The electronics enclosure 14 houses telecommunications equipment (e.g., devices 1, 2, and 3 in FIG. 3). A power panel 22 (see, e.g., FIG. 12) is disposed on the second side of the cabinet 20. The power panel 22 provides electrical connections 50 and power source(s) 52 for the telecommunications equipment in the electronics enclosure 14 of the cabinet 20.

In an example, the cabinet 20 is configured to be installed as a base for a telecommunications pole, which is mounted at attachment 11 with bolts on top of the cabinet 20. The top portion of the shroud wraps around or is enclosed on a section of the pole (not shown, but extending upward from within opening 5). For example, the cabinet 20 shroud may have a first half and a second half. The first half of the cabinet 20 shroud fits around a first side of the pole, and the second half of the cabinet 20 shroud fits around a second (opposite) side of the pole. When fully assembled, the cabinet 20 shroud entirely surrounds the base of the pole that is installed on the cabinet.

In an example, the cabinet 20 is configured to be installed at the base of a pole, e.g., as a lower cabinet for street level access. However, the cabinet 20 may be installed at any suitable height on the pole, including at or near the top of the pole and anywhere in between the base and the top. In addition, the cabinet 20 may be freestanding and provided separately from any poles. In this example, a cover can be provided over the opening 5.

In an example, the cabinet 20 exterior or shroud is manufactured of a lighter gauge formed metal or composite plastic doors than the interior support. The shroud can be of any shape (e.g., square, rectangular, etc.) and may be aesthetically pleasing and/or comport with government or community guidelines or other requirements. The doors when closed, wrap the inside structure of the cabinet 20 to provide a weather tight seal to protect the equipment inside the cabinet.

Additional aesthetic considerations may include the cabinet 20 shroud concealing flange connections. The hardware uses a four-piece system, where identical corners are made to be cast or machined. Flat trim pieces fill gaps between the corners to enable variable size structural members.

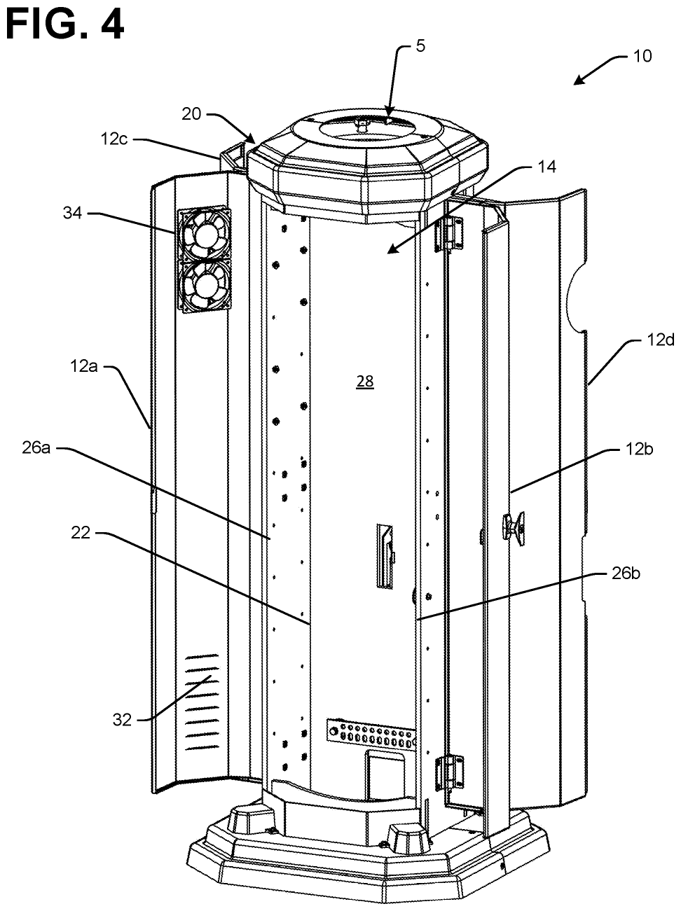

FIG. 3 is a perspective view of a first side of an example small cell telecommunication structure 10 with the first side enclosure doors 12a and 12b shown open. FIG. 4 corresponds to FIG. 3, and shows electronics (e.g., devices 1, 2, and 3 in FIG. 3) and shelving (e.g., shelving 4 in FIG. 3) removed from an interior portion of the first side of the example small cell telecommunication structure 10.

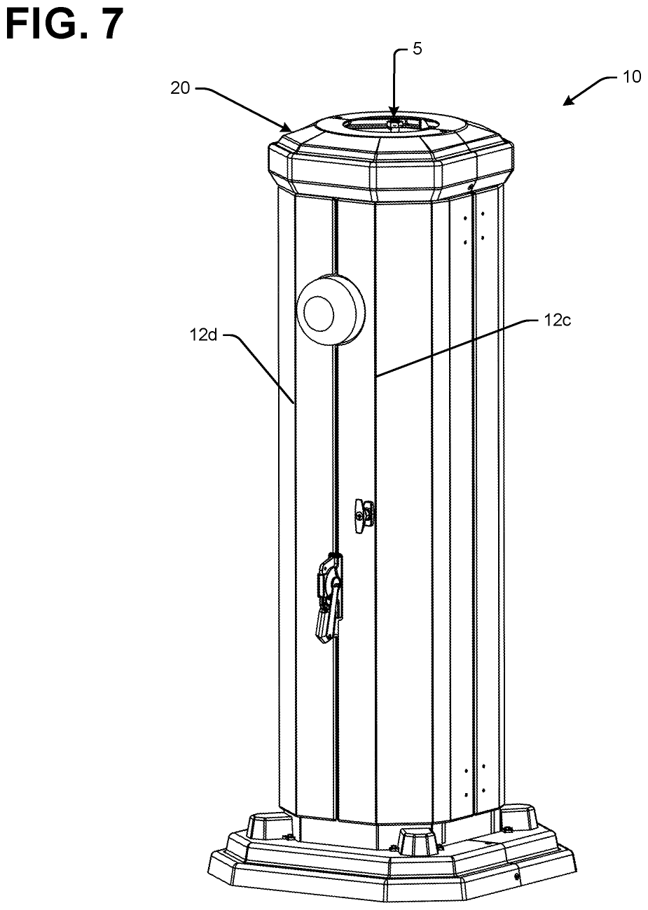

In an example, the cabinet 20 opens both on a first side (FIGS. 3 and 4) and on a second side (FIGS. 7-11). The first side of the cabinet 20 is disposed opposite to the second side of the cabinet 20. This is illustrated by way of example in the drawings, with the doors 12a-b and 12c-d disposed on directly opposite sides from one another.

A structural backplane 24 is provided within the cabinet 20. In an example, the structural backplane 24 is made of a single slotted and tabbed flat sheet that is formed into a first sidewall 26a, a back wall 28, and a second sidewall 26b. The first sidewall 26a is parallel to the second sidewall 26b, and both the first and second sidewalls 26a, 26b are perpendicular to the back wall 28.

In an example, the interior space of the electronics enclosure 14 is formed by the first and second sidewalls 26a, 26b and the back wall 28 of the structural backplane 24. In an example, the first and second sidewalls 26a, 26b and the back wall 28 of the structural backplane 24 provide a substantially flat and rectangular interior space of the electronics enclosure 14. This configuration enables the interior of the cabinet 20 to efficiently accommodate substantially flat and rectangular telecommunications equipment (e.g., devices 1, 2, and 3 in FIG. 3).

In an example, the electronics enclosure 14 includes a backplane 24 that is a separate piece from the cabinet 20 (e.g., stand-alone from the exterior or shroud) so that the backplane electronics (e.g., devices 1, 2, and 3 in FIG. 3) can be wired at the same time these are installed in the cabinet 20, without having to wait for the entire assembly. This eliminates the critical path schedule of having to wait for the cabinet 20 to be completed before proceeding to install and/or connect the electronics.

The cabinet 20 can be accessed via at least one door 12a, 12b and 12c, 12d on each side. In an example, a first pair of cabinet doors 12a, 12b provide access to the first side of the cabinet 20 (e.g., the electronics enclosure 14), and a second pair of cabinet doors 12c, 12d provides access to the second side of the cabinet 20 (e.g., the power panel 22. The cabinet doors 12a-d may be hinged.

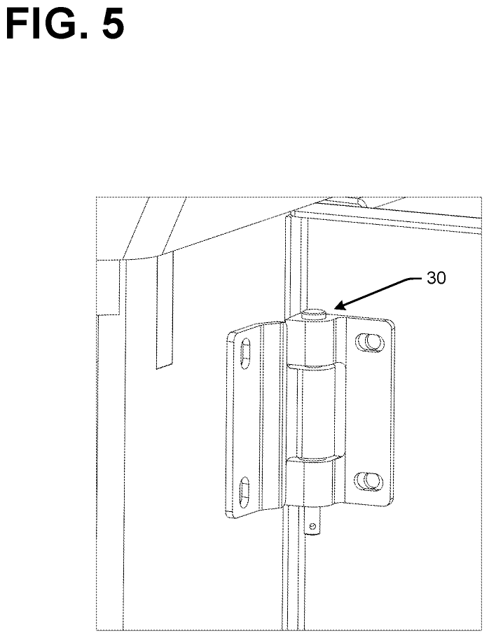

FIG. 5 is a close-up view of an example hinge 30 seen in FIGS. 3 and 4. In an example, the cabinet doors 12a-d utilize door hinges 30 that are cast. The cast hinges 30 allow for manufacturing identical components in large volumes.

In an example, the cabinet doors 12a-d have one or more structural bend to provide structural support for the door panel. The cabinet doors 12a-d are shown in the drawings having a roughly “trough” shape formed by two bends along the length of the doors. However, other structural bends and/or other supports may also be provided for the cabinet doors 12a-d.

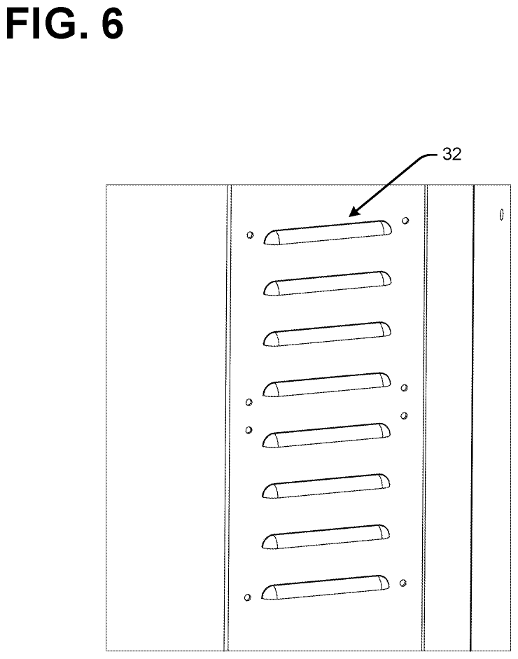

In an example, one or more of the doors 12a-d of the cabinet 20 may have louvers to permit airflow and help prevent overheating of the electronic devices (e.g., devices 1, 2, and 3 in FIG. 3) installed in the cabinet 20. FIG. 6 is a close-up view of an example louver 32 seen in FIGS. 3 and 4. The louver 32 vents are configured to help prevent water ingress into the structure, while permitting airflow within the interior of the cabinet 20 to help prevent overheating of the electronics devices installed in the cabinet 20.

In an example, at least one active ventilation device is provided in the cabinet 20 to facilitate airflow. For example, one or more fans 34 can be attached to the interior of the cabinet doors 12a-b (and/or 12c-d). The fan(s) 34 may be installed directly over the louvers 32 formed in the cabinet doors. Air is drawn in the lower louvers 32 near the bottom of the doors 12a-b, circulates through the interior chamber around the telecommunications equipment in the electronics enclosure 14, and is blown out of the cabinet into the environment by the fans 34. Of course, the fans 34 may be mounted in any convenient location and according to any directional operation to enhance airflow.

Insulation may also be provided in some or all of the cabinet 20. In an example, reflective insulation is provided inside the cabinet 20 shroud to help reduce heat generated by the equipment and/or from solar radiation.

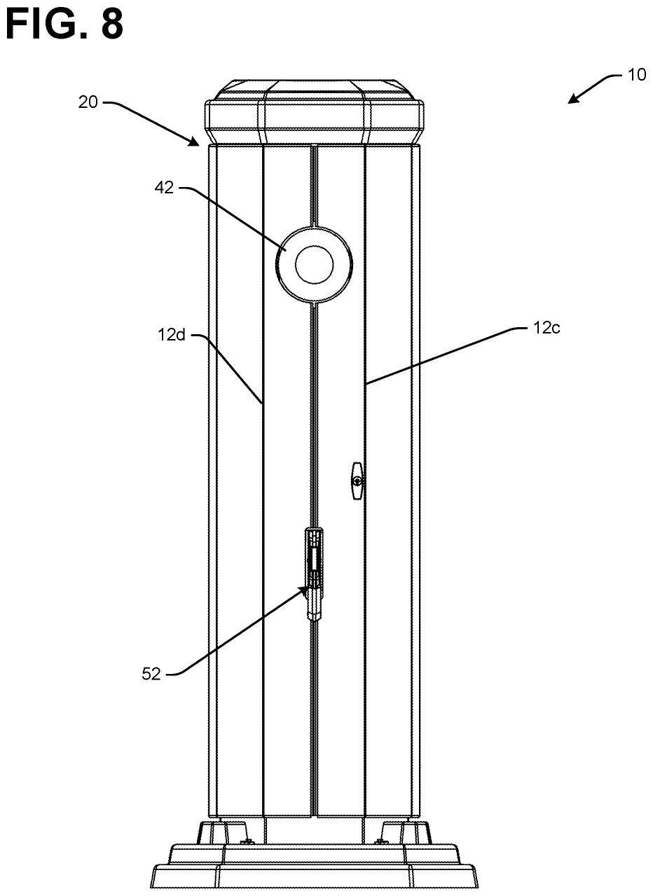

FIG. 7 is a perspective view of a second side of the example small cell telecommunication structure 10. The second side of the cabinet 20 is configured to provide power to the electronic devices (e.g., devices 1, 2, and 3 in FIG. 3) in the electronics enclosure 14 on the opposite side of the cabinet 20. FIG. 8 is a plan view corresponding to FIG. 7.

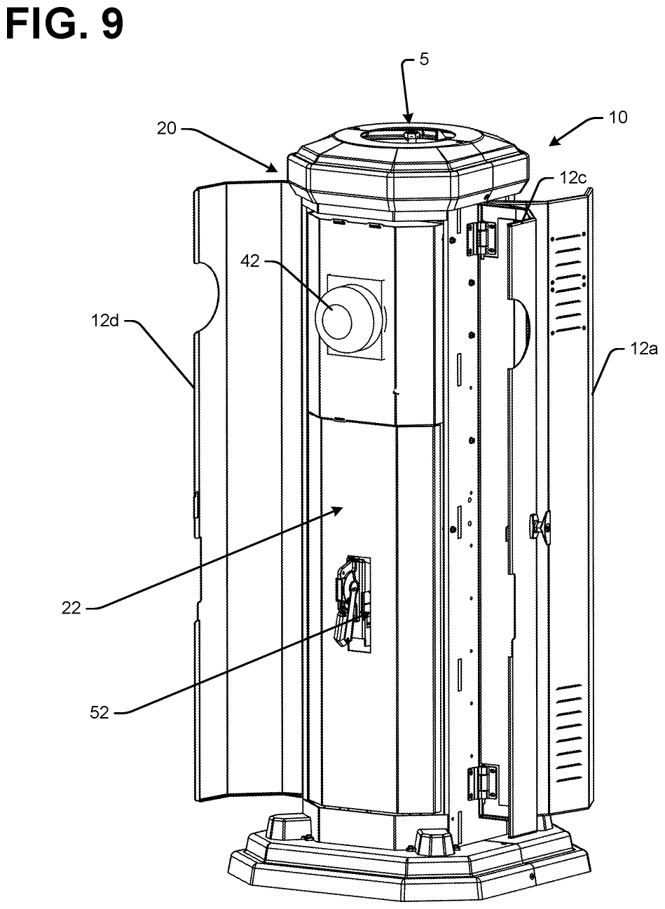

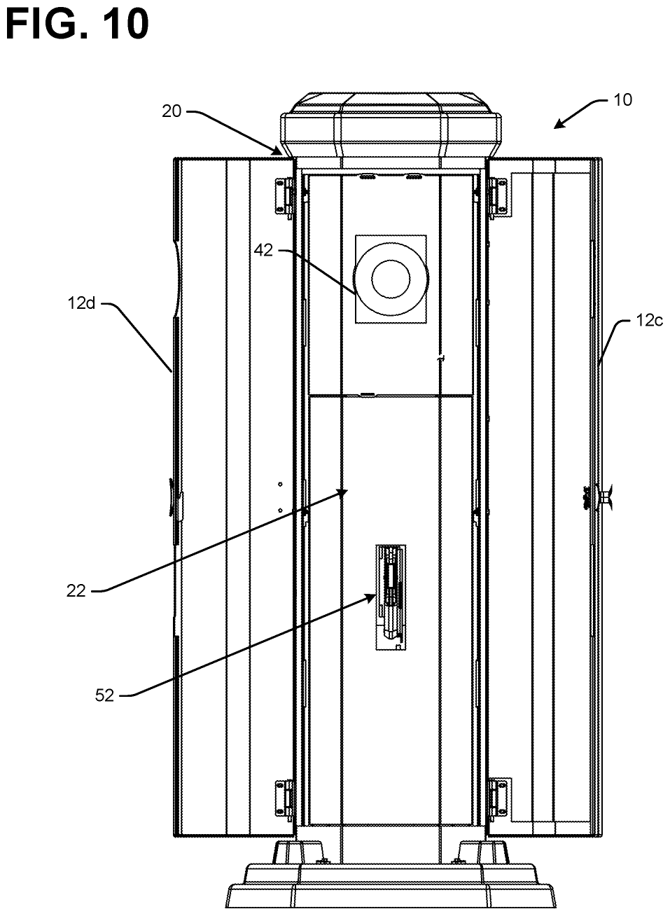

FIG. 9 is a perspective view of the second side of the example small cell telecommunication structure 10 with the enclosure doors 12c, 12d shown open. FIG. 10 is a plan view corresponding to FIG. 9. The second side of the cabinet 20 includes the power panel 22 (see, e.g., FIG. 12). The power panel 22 provides electrical power and is used to make electrical connections for the telecommunications equipment (e.g., devices 1, 2, and 3 in FIG. 3) in the electronics enclosure 14 of the cabinet 20.

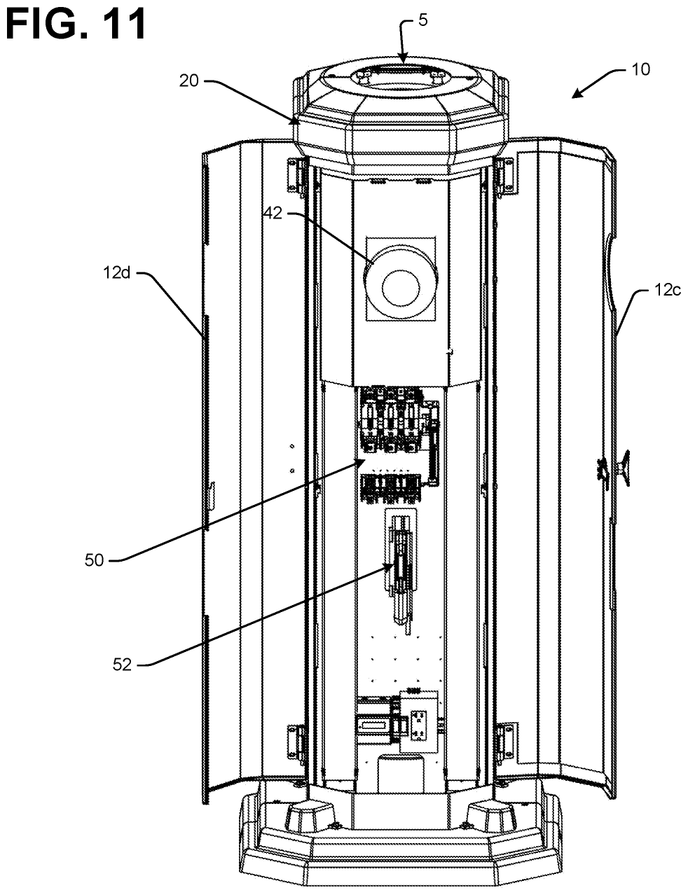

FIG. 11 is a perspective view of the second side of the example small cell telecommunication structure 10 with an interior cover 40 of the power panel 22 removed to show the electrical panel for making electrical connections. FIG. 12 is a perspective view of the example power panel 22 for the example small cell telecommunication structure 10. The power panel 22 may be removed entirely from the cabinet shroud. The power panel 22 may also be installed back to back onto the backplane 24 independent of the cabinet 20 shroud. This enables the electronic devices and power to be installed and all connections made without the shroud in place, and then the shroud can be installed. Cabinet doors 12a-d provide access to the electronic devices and power panel 22 after the cabinet 20 shroud is installed, to enable repairs and upgrades without having to remove the shroud from the cabinet 20.

In an example, the backplane 24 and doors 12c, 12d of the cabinet 20 are configured to provide the option of providing either an integrated meter 42, or to separately install a standard meter (e.g., one that is already approved by the municipality or power authority). The meter integrated with the doors gives the cabinet 20 an aesthetically pleasing appearance, and provides a better solution to an aesthetic challenge in many cities and towns where the approving body cares what the structure looks like.

It is noted that the examples shown and described are provided for purposes of illustration and are not intended to be limiting. Still other examples are also contemplated.

1. A small cell telecommunication structure, comprising:
a cabinet opening both on a first side and on a second side, the first side disposed opposite to the second side;
a structural backplane within the cabinet, the structural backplane made of a single slotted and tabbed flat sheet formed into a first sidewall, a back wall, and a second sidewall, the first sidewall parallel to the second sidewall, and both the first and second sidewalls perpendicular to the back wall;
an electronics enclosure within the cabinet, the electronics enclosure having an interior space formed by the first and second sidewalls and the back wall of the structural backplane for housing telecommunications equipment; and
a power panel disposed on the second side of the cabinet, the power panel providing electrical connections for the telecommunications equipment.

2. The small cell telecommunication structure of claim 1, wherein the cabinet is configured to be installed as a base for a pole.

3. The small cell telecommunication structure of claim 2, wherein the cabinet has a shroud with a first half and a second half, the first half of the shroud fitting around a first side of the pole and the second half of the shroud fitting around a second, opposite side of the pole so that the cabinet appears to entirely surround the pole when the pole is installed on the cabinet.

4. The small cell telecommunication structure of claim 1, wherein the cabinet is configured to be installed other than at the base of a pole.

5. The small cell telecommunication structure of claim 1, further comprising a first pair of cabinet doors to close the first side of the cabinet, and a second pair of cabinet doors to close the second side of the cabinet.

6. The small cell telecommunication structure of claim 5, further comprising fans attached to the interior of the first pair of cabinet doors over louvers formed in the first pair of cabinet doors to provide airflow for the telecommunications equipment in the electronics enclosure.

7. The small cell telecommunication structure of claim 5, wherein the first pair of cabinet doors and the second pair of cabinet doors each have at least one bend configured for door panel structural structural support.

8. The small cell telecommunication structure of claim 1, wherein the first and second sidewalls and the back wall of the structural backplane provide a substantially flat and rectangular interior space configured to efficiently accommodate substantially flat and rectangular telecommunications equipment.

9. The small cell telecommunication structure of claim 1, further comprising equipment mounting locations on the first and second sidewalls and on the back wall of the structural backplane, the equipment mounting locations provided for mounting the telecommunications equipment.

10. The small cell telecommunication structure of claim 9, further comprising slotted connectors for installing backplanes of the telecommunications equipment in the cabinet without tools for installation.

11. The small cell telecommunication structure of claim 1, wherein the power panel is removable from the cabinet.

12. The small cell telecommunication structure of claim 1, further comprising an integrated electrical power meter.

13. The small cell telecommunication structure of claim 1, further comprising at least one active ventilation device in the cabinet.

14. The small cell telecommunication structure of claim 1, further comprising reflective insulation of the cabinet.

15. A small cell telecommunication structure, comprising:
a cabinet opening both on a first side and on a second side, the first side disposed opposite to the second side, wherein the cabinet is configured to be installed as a base of a pole;
a first pair of cabinet doors to close the first side of the cabinet, and a second pair of cabinet doors to close the second side of the cabinet;
a structural backplane within the cabinet, the structural backplane made of a single slotted and tabbed flat sheet formed into a first sidewall, a back wall, and a second sidewall, the first sidewall parallel to the second sidewall, and both the first and second sidewalls perpendicular to the back wall;
an electronics enclosure within the cabinet, the electronics enclosure having an interior space formed by the first and second sidewalls and the back wall of the structural backplane for housing telecommunications equipment; and
a power panel disposed on the second side of the cabinet, the power panel providing electrical connections for the telecommunications equipment.

16. The small cell telecommunication structure of claim 15, wherein the cabinet has a shroud with a first half and a second half, the first half of the shroud fitting around a first side of the pole and the second half of the shroud fitting around a second, opposite side of the pole so that the cabinet appears to entirely surround the pole when the pole is installed on the cabinet.

17. The small cell telecommunication structure of claim 15, further comprising equipment mounting locations on the first and second sidewalls and on the back wall of the structural backplane, the equipment mounting locations provided for mounting the telecommunications equipment.

18. The small cell telecommunication structure of claim 15, wherein the first and second sidewalls and the back wall of the structural backplane provide a substantially flat and rectangular interior space configured to efficiently accommodate substantially flat and rectangular telecommunications equipment.

19. The small cell telecommunication structure of claim 15, further comprising at least one active ventilation device in the cabinet.
